(19) United States
(12) Patent Application Publication
(10) Pub. No.: US 2025/0056762 A1
(43) Pub. Date: Feb. 13, 2025

(54) DUAL LIQUID-COOLING RADIATOR FOR SEMICONDUCTOR REFRIGERATION SYSTEM

(71) Applicant: Dongguan Ice Point Intelligent Technology Co., Ltd, Dongguan City (CN)

(72) Inventor: Fengqi Zhang, Dongguan (CN)

(21) Appl. No.: 18/931,924

(22) Filed: Oct. 30, 2024

(51) Int. Cl. H05K 7/20; F25B 21/02

(52) U.S. Cl. CPC H05K 7/20272; F25B 21/02; F25B 2321/0252

(57) ABSTRACT

The present disclosure discloses a dual liquid-cooling radiator for a semiconductor refrigeration system, including a first upper cold head module, a first lower cold head module, a second cold head module, and a semiconductor refrigeration chip. The temperature of a first liquid-cooling radiator is reduced through the conduction of the semiconductor refrigeration chip to reduce the temperature of a CPU. The heat generated by the semiconductor refrigeration chip is conducted through the second cold head module to reduce the temperature. A temperature control PCB adjusts the cooling temperature of the semiconductor refrigeration chip according to the temperature of the computer. A first water-cooled pipe and a second water-cooled pipe use a quick disassembly and assembly structure.

### TECHNICAL FIELD

The present disclosure relates to the technical field of heat dissipation devices, specifically a dual liquid-cooling radiator for a semiconductor refrigeration system.

### BACKGROUND

As the performance of computer systems gradually improves, the heat generated by the operation of electronic components such as CPUs also inevitably increases. In order to solve the heating problem, a heat dissipation system is usually required to quickly dissipate heat, so as to prevent electronic components from being reduced in life or damaged due to overheating.

A high-efficiency water-cooled radiator provided by the utility model with the application number CN219105445U includes a heat-conducting assembly, an air-cooled assembly, and a water-cooled assembly. After the user attaches and installs the heat sink to the electronic components that needs heat dissipation, the heat of the electronic component is conducted to the heat sink. The circulating liquid in the water-cooled assembly enters the water outlet tank, then sprays from the water outlet on the waterway cover plate to the middle of the micro water channel, flows to the surroundings of the micro water channel, then flows from the water inlet on the waterway cover plate into the water inlet tank, and finally flows from the inlet water tank into the water-cooled assembly for heat dissipation to achieve water-cooled heat dissipation of the water electronic component. After the air-cooled fan is started, air enters from the air inlet and blows out from the air outlet. The air blowing from around the air-cooled cover blows away the heat emitted around the electronic component, thus solving the problem of heat dissipation around the electronic component. However, the heat transfer rate of this type of radiator is average, causing the heat dissipation efficiency of the CPU radiator to be unsatisfactory. Therefore, there is an urgent need to design a radiator which can directly and quickly cool the heat sink through the semiconductor refrigeration chip, so that the cooled heat sink can quickly reduce the temperature of the motherboard CPU, and the heat generated by the cooling of the semiconductor refrigeration chip can be reduced for cooling through the second liquid-cooling radiator.

### SUMMARY

In order to overcome the shortcomings of the existing technical solutions, the present disclosure provides a dual liquid-cooling radiator for a semiconductor refrigeration system, which can effectively solve the technical problem of unsatisfactory heat dissipation efficiency of the CPU radiator of the current water-cooled radiator due to the average heat transfer rate of the radiator.

The technical solution used by the present disclosure to solve the technical problem is: A dual liquid-cooling radiator for a semiconductor refrigeration system includes a semiconductor refrigeration assembly, a first liquid-cooling radiator assembly, a second liquid-cooling radiator assembly, a first water-cooled row, a second water-cooled row, a first water-cooled pipe, and a second water-cooled pipe, where the first liquid-cooling radiator assembly is connected to the first water-cooled row through the first water-cooled pipe, and the second liquid-cooling radiator assembly is connected to the second water-cooled row through the second water-cooled pipe; and
the first liquid-cooling radiator assembly includes a front shell, a rear shell, a first upper cold head module, and a first lower cold head module, where the front shell and the rear shell are snap-fitted to each other, the first upper cold head module is assembled at the front end of the front shell, the first lower cold head module is assembled at the rear end of the rear shell, the second liquid-cooling radiator assembly includes a housing and a second cold head module, where the second cold head module is assembled at the rear end of the housing, and the semiconductor refrigeration assembly includes a semiconductor refrigeration chip assembled between the second cold head module and the first upper cold head module.

Further, the semiconductor refrigeration assembly also includes a temperature control PCB electrically connected to the semiconductor refrigeration chip to control the temperature of the semiconductor refrigeration chip.

Further, the first upper cold head module includes an upper waterway cover plate, an upper waterway rubber and an upper heat sink that are arranged in sequence from inside to outside, a first water reservoir is disposed in the middle of the front shell, the front shell is closed by the upper waterway cover plate, a first water inlet tunnel and a first water outlet tunnel are spaced apart in the first water reservoir, a first water spray tank is disposed in the middle of the upper waterway cover plate, a first water trough is disposed in the middle of the upper waterway rubber, a first micro water channel is arranged in the upper heat sink, the first water inlet tunnel communicates with the first water spray tank, the outlet direction of the first water spray tank is disposed facing the upper heat sink, a first water outlet is disposed on each of the upper and lower sides of the upper waterway cover plate, and the first water outlets communicate with the first water outlet tunnel.

Further, the first lower cold head module includes a first lower waterway cover plate, a first lower waterway rubber and a first lower heat sink that are arranged in sequence from inside to outside, a second water reservoir is disposed in the middle of the rear shell, the rear shell is closed by the first lower waterway cover plate, a second water inlet tunnel and a second water outlet tunnel are spaced apart in the second water reservoir, a second water spray tank is disposed in the middle of the first lower waterway cover plate, a second water trough is disposed in the middle of the first lower waterway rubber, a second micro water channel is arranged in the first lower heat sink, the second water inlet tunnel communicates with the second water spray tank, the outlet direction of the second water spray tank is disposed facing the first lower heat sink, a second water outlet is disposed on each of the upper and lower sides of the first lower waterway cover plate, and the second water outlets communicate with the second water outlet tunnel.

Further, the front shell is provided with a first water inlet orifice and a first water outlet orifice, the rear shell is provided with a first water inlet channel and a first water outlet channel, the first water inlet channel communicates with the first water inlet orifice, the first water inlet orifice communicates with the first water inlet tunnel, the first water outlet orifice communicates with the first water outlet tunnel and the second water inlet tunnel respectively, and the second water outlet tunnel communicates with the first water outlet channel.

Further, the second cold head module includes a second lower waterway cover plate, a second lower waterway rubber and a second lower heat sink that are arranged in sequence from inside to outside, a third water reservoir is disposed in the middle of the housing, the housing is closed by the second lower waterway cover plate, a third water inlet tunnel and a third water outlet tunnel are spaced apart in the third water reservoir, a third water spray tank is disposed in the middle of the second lower waterway cover plate, a third water trough is disposed in the middle of the second lower waterway rubber, a third micro water channel is arranged in the second lower heat sink, the third water inlet tunnel communicates with the third water spray tank, the outlet direction of the third water spray tank is disposed facing the second lower heat sink, a third water outlet is disposed on each of the left and right sides of the second lower waterway cover plate, and the third water outlets communicate with the third water outlet tunnel.

Further, the housing is provided with a second water inlet channel and a second water outlet channel, the second water inlet channel communicates with the second water inlet tunnel, and the second water outlet channel communicates with the second water outlet tunnel.

Further, the front shell is provided with a first sealing groove configured to surround the outer periphery of the first water reservoir; a first waterway sealing ring is assembled in the first sealing groove, and the first waterway sealing ring is in contact with the inner surface of the upper heat sink; the rear shell is provided with a second sealing groove configured to surround the outer periphery of the second water reservoir; a second waterway sealing ring is assembled in the second sealing groove, and the second waterway sealing ring is in contact with the inner surface of the first lower heat sink; the housing is provided with a third sealing groove configured to surround the outer periphery of the third water reservoir; a third waterway sealing ring is assembled in the third sealing groove, and the third waterway sealing ring is in contact with the inner surface of the second lower heat sink.

Further, the first water-cooled pipe includes a first water inlet pipe and a first water outlet pipe, one end of the first water inlet pipe is connected to the first water inlet channel, the other end of the first water inlet pipe is connected to the first water-cooled row, one end of the first water outlet pipe is connected to the first water outlet channel, the other end of the first water outlet pipe is connected to the first water-cooled row, the first water-cooled row is also mounted with a first fan assembly, and an air inlet of the first fan assembly is disposed facing the first water-cooled row.

Further, the second water-cooled pipe includes a second water inlet pipe and a second water outlet pipe, one end of the second water inlet pipe is connected to the second water inlet channel, the other end of the second water inlet pipe is connected to the second water-cooled row, one end of the second water outlet pipe is connected to the second water outlet channel, the other end of the second water outlet pipe is connected to the second water-cooled row, the second water-cooled row is also mounted with a second fan assembly, and an air inlet of the second fan assembly is disposed facing the second water-cooled row.

Compared with the prior art, the beneficial effects of the present disclosure are:

The first liquid-cooling radiator assembly is connected to the first water-cooled row through the first water-cooled pipe, the second liquid-cooling radiator assembly is connected to the second water-cooled row through the second water-cooled pipe, the first upper cold head module is assembled at the front end of the front shell, the first lower cold head module is assembled at the rear end of the rear shell, the second cold head module is assembled at the rear end of the housing, the semiconductor refrigeration chip is assembled between the second cold head module and the first upper cold head module, and the first lower cold head module is placed close to the outer end face of the CPU. The liquid-cooled temperature of the first liquid-cooling radiator is reduced through the conduction of the semiconductor refrigeration chip to reduce the temperature of the CPU. The heat generated by the refrigeration of the semiconductor refrigeration chip is conducted through the second cold head module to reduce the temperature. On the one hand, the second cold head module cools the heating surface of the semiconductor refrigeration chip, which can solve the problem of the semiconductor refrigeration chip in the refrigeration process due to the cooling-heating imbalance, resulting in water droplets produced around the heat sink that will burn equipment of the computer. On the other hand, this structural method for cooling the temperature of the motherboard CPU goes beyond the traditional original cooling system and other cooling system methods, and can truly reduce the temperature of the motherboard CPU more effectively.

### BRIEF DESCRIPTION OF DRAWINGS

FIG. 1 is a schematic diagram of an overall structure of a dual liquid-cooling radiator for a semiconductor refrigeration system according to the present disclosure;

FIG. 2 is an exploded structural view of a dual liquid-cooling radiator for a semiconductor refrigeration system according to the present disclosure;

FIG. 3 is an exploded structural view of a first liquid-cooling radiator and a second liquid-cooling radiator in a dual liquid-cooling radiator for a semiconductor refrigeration system according to the present disclosure;

FIG. 4 is a schematic structural diagram of a front shell in a dual liquid-cooling radiator for a semiconductor refrigeration system according to the present disclosure;

FIG. 5 is a schematic diagram of an assembly structure of an upper heat sink and an upper waterway cover plate in a dual liquid-cooling radiator for a semiconductor refrigeration system according to the present disclosure;

FIG. 6 is a schematic structural diagram of a rear shell in a dual liquid-cooling radiator for a semiconductor refrigeration system according to the present disclosure;

FIG. 7 is a schematic diagram of an assembly structure of a first lower heat sink and a first lower waterway cover plate in a dual liquid-cooling radiator for a semiconductor refrigeration system according to the present disclosure;

FIG. 8 is an exploded structural view of a second liquid-cooling radiator from the front view in a dual liquid-cooling radiator for a semiconductor refrigeration system according to the present disclosure;

FIG. 9 is an exploded structural view of the second liquid-cooling radiator from the rear view in a dual liquid-cooling radiator for a semiconductor refrigeration system according to the present disclosure;

FIG. 10 is a schematic diagram of a flow direction of the cooling liquid in the first liquid-cooling radiator in a dual liquid-cooling radiator for a semiconductor refrigeration system according to the present disclosure;

FIG. 11 is a schematic diagram of a flow direction of the cooling liquid of the second liquid-cooling radiator in a dual liquid-cooling radiator for a semiconductor refrigeration system according to the present disclosure;

FIG. 12 is a schematic diagram of an assembly structure of a first water pump, a first water inlet pipe, a second water pump and a second water inlet pipe in a dual liquid-cooling radiator for a semiconductor refrigeration system according to the present disclosure;

FIG. 13 is an enlarged structural view of portion A in FIG. 11; and

FIG. 14 is a schematic structural diagram of the first water inlet pipe or a first water outlet pipe or the second water inlet pipe or a second water outlet pipe in a dual liquid-cooling radiator for a semiconductor refrigeration system according to the present disclosure.

### REFERENCE NUMERALS IN FIGURES

first liquid-cooling radiator 100; first water inlet channel 101; first water outlet channel 102; first water inlet pipe 103; first water outlet pipe 104; first water-cooled row 105; first fan assembly 106; front shell 107; first water outlet 108; first water spray tank 109; upper waterway rubber 110; upper heat sink 111; first waterway sealing ring 112; first water trough 113; upper waterway cover plate 115; first sealing groove 116; rear shell 117; second water outlet 118; second water trough 119; second micro water channel 120; first lower heat sink 121; second waterway sealing ring 122; first lower waterway rubber 123; first lower waterway cover plate 124; second water spray tank 125; first water inlet orifice 127; first water inlet tunnel 128; first water outlet orifice 129; first water outlet tunnel 130; first micro water channel 133; second water outlet tunnel 134; second water inlet tunnel 135;
second liquid-cooling radiator 200; second water inlet channel 201; second water outlet channel 202; second lower heat sink 203; third waterway sealing ring 204; second lower waterway rubber 205; third micro water channel 206; third water trough 207; third water outlet 208; third water spray tank 209; second water inlet pipe 210; second outlet pipe 211; third water outlet tunnel 212; third sealing groove 213; third water inlet tunnel 214; housing 215; second water-cooled row 216; second fan assembly 217; second lower waterway cover plate 218;
semiconductor refrigeration assembly 300; semiconductor refrigeration chip 301; temperature control PCB 302; first water pump 303; second water pump 304; pipe sleeve 305; adapter 306; second connecting pipe 307; connector 308; butt joint 309; first connecting pipe 310.

### DETAILED DESCRIPTION

The technical solution in the embodiments of the present disclosure will be clearly and completely described below in conjunction with the accompanying drawings in the embodiments of the present disclosure. Obviously, the described embodiments are merely some of the embodiments of the present disclosure, rather than all of the embodiments. Based on the embodiments of the present disclosure, all other embodiments obtained by those of ordinary skill in the art without creative efforts fall within the scope of protection of the present disclosure.

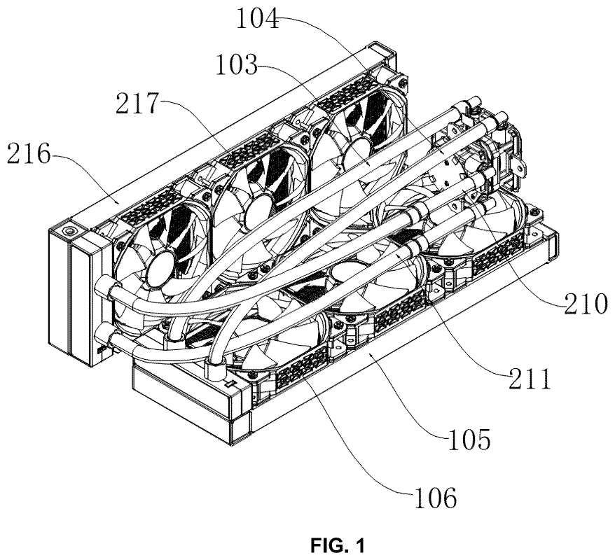

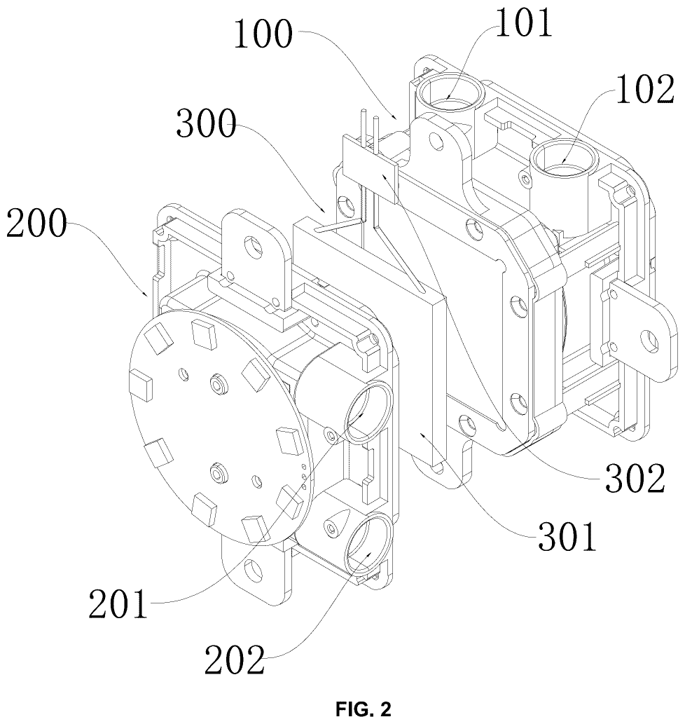

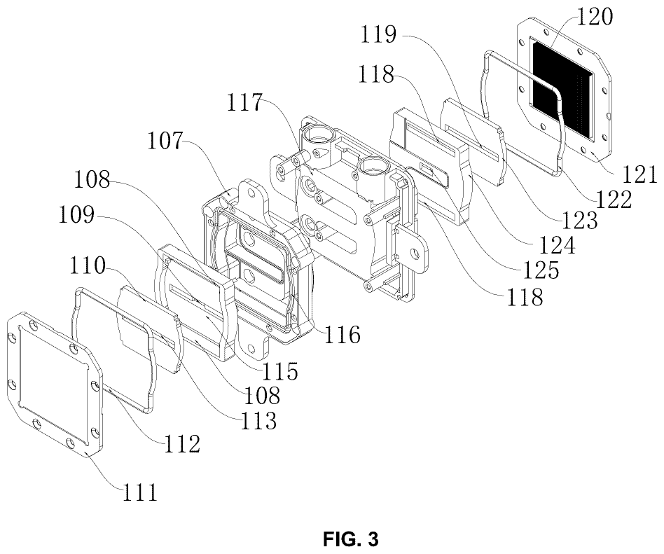

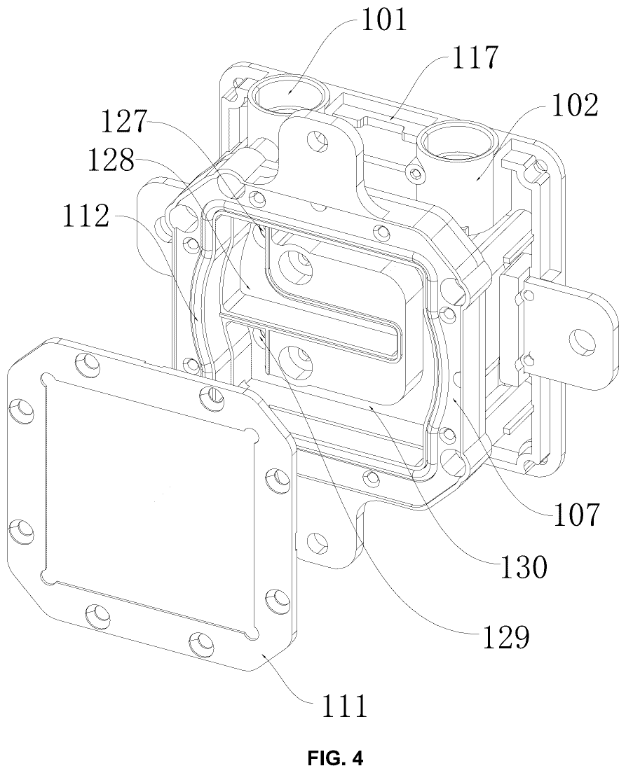

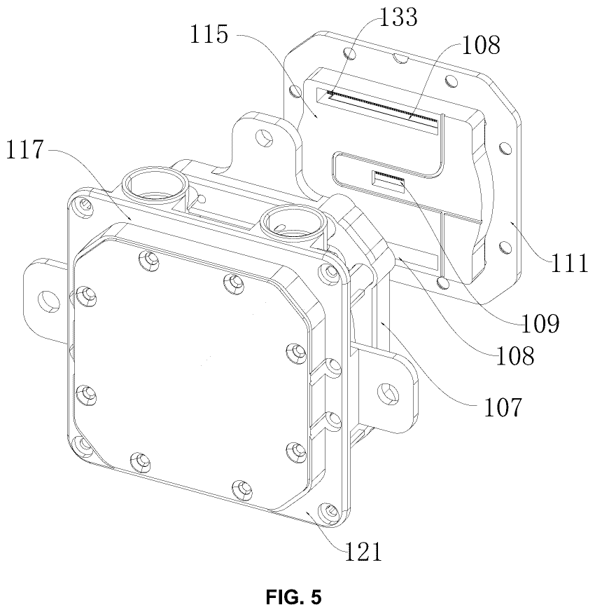

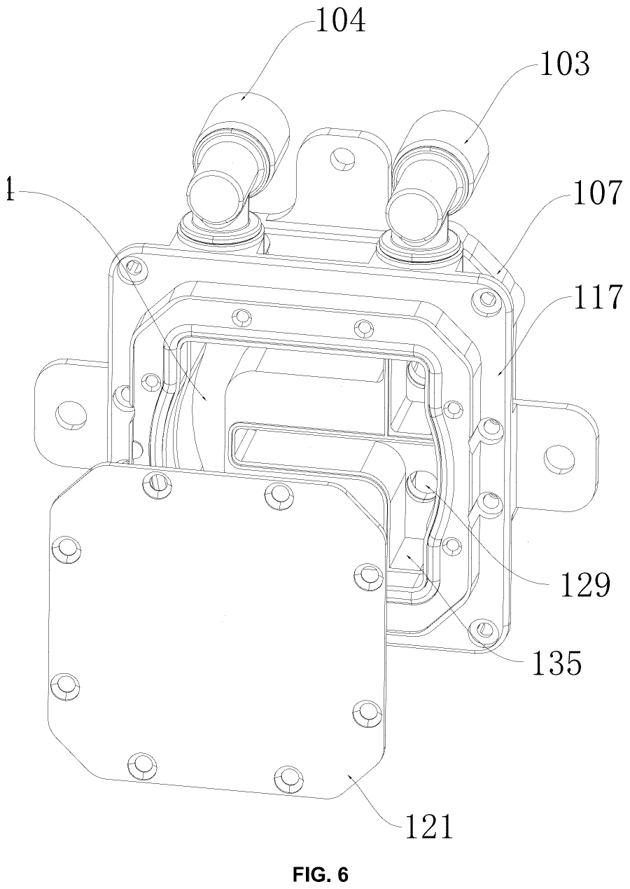

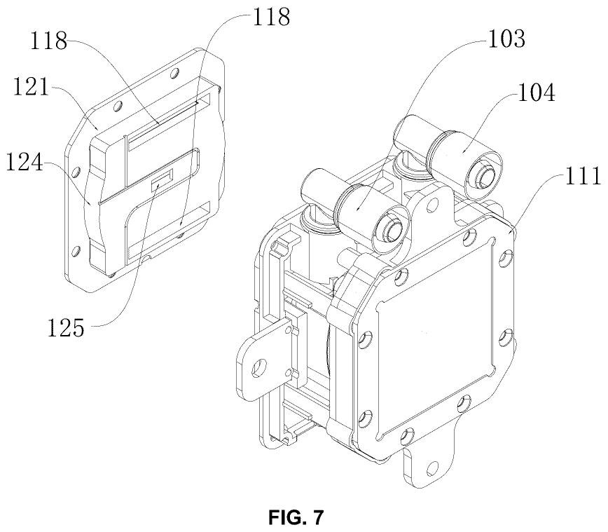

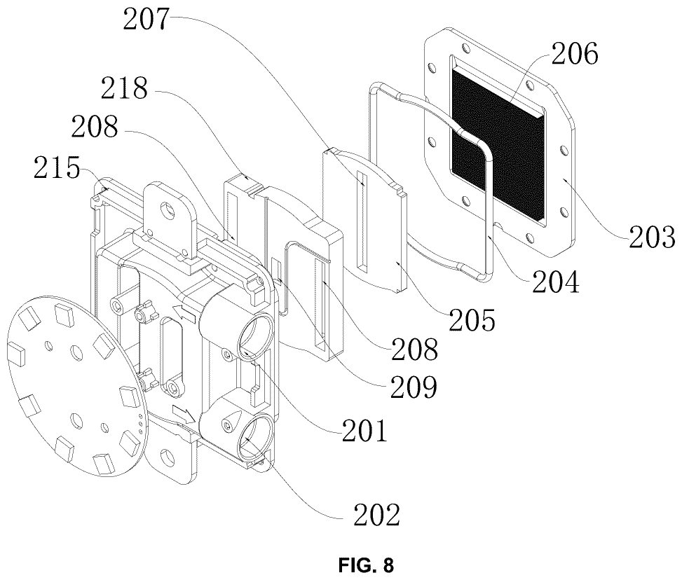

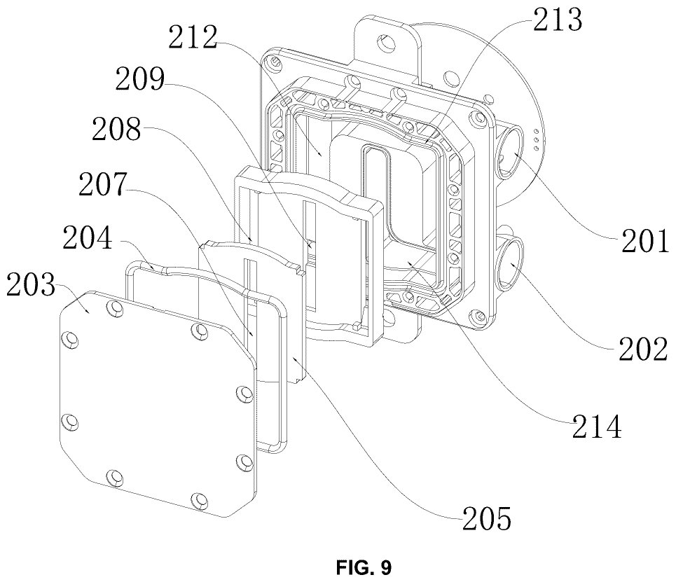

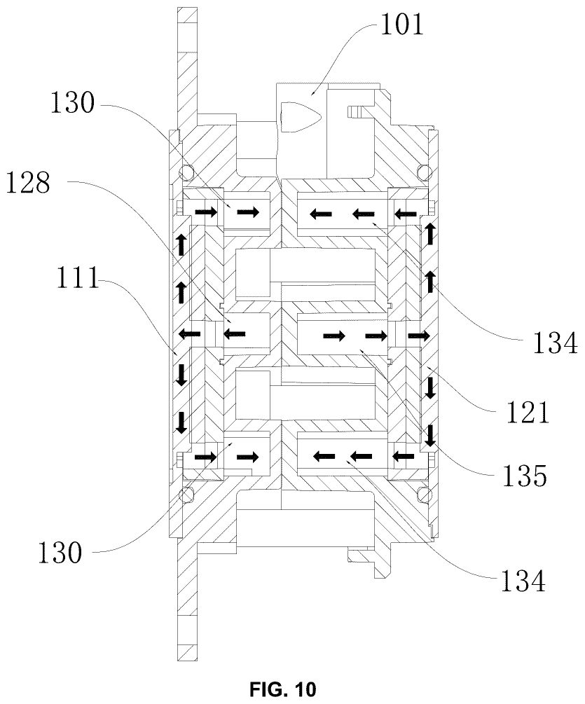

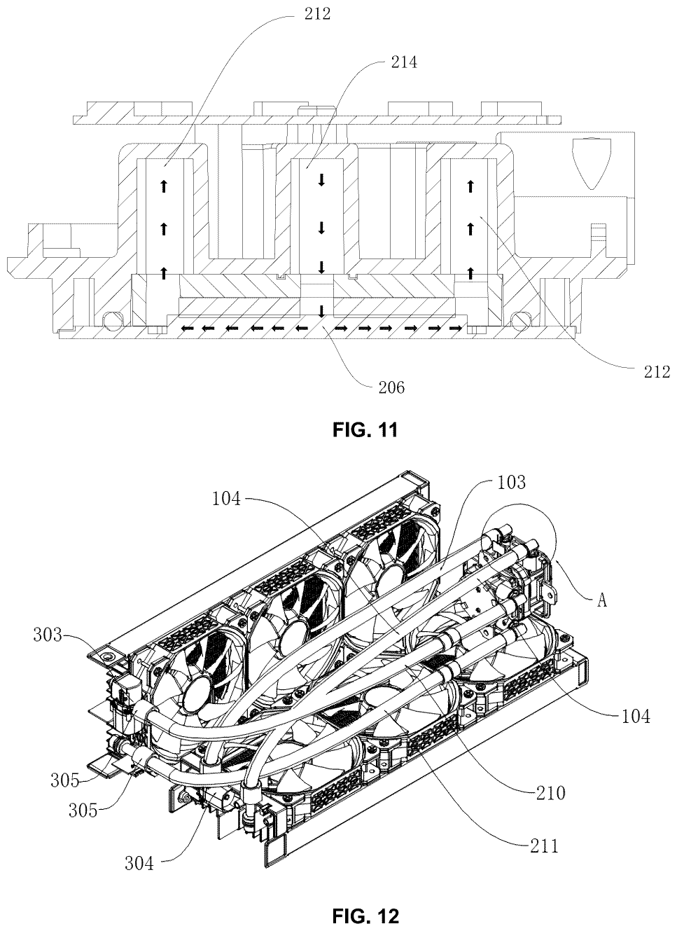

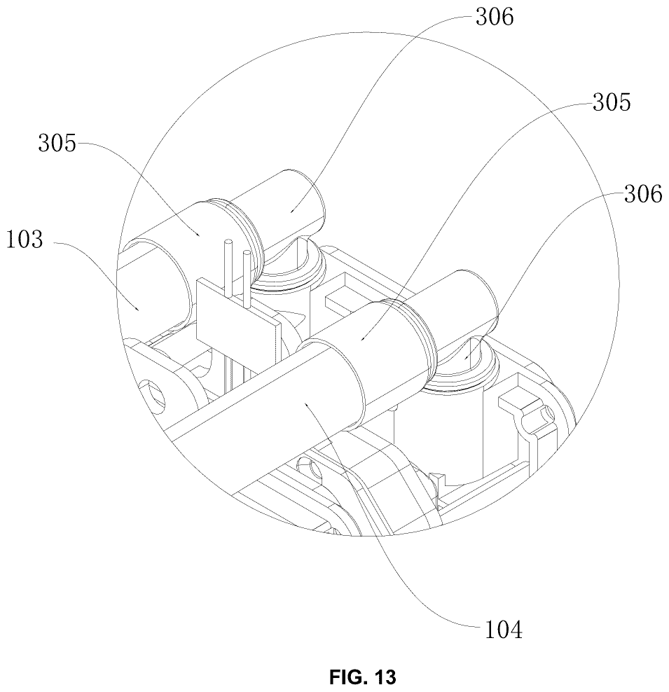

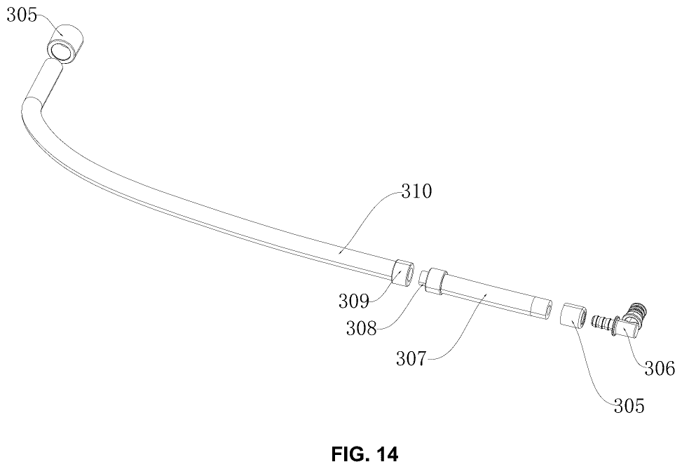

As shown in FIGS. 1-14, the present disclosure provides a dual liquid-cooling radiator for a semiconductor refrigeration system, including a semiconductor refrigeration assembly 300, a first liquid-cooling radiator 100 assembly, a second liquid-cooling radiator 200 assembly, a first water-cooled row 105, a second water-cooled row 216, a first water-cooled pipe, and a second water-cooled pipe. The first liquid-cooling radiator 100 assembly is connected to the first water-cooled row 105 through the first water-cooled pipe, and the second liquid-cooling radiator 200 assembly is connected to the second water-cooled row 216 through the second water-cooled pipe.

The first liquid-cooling radiator 100 assembly includes a front shell 107, a rear shell 117, a first upper cold head module, and a first lower cold head module. The front shell 107 and the rear shell 117 are snap-fitted to each other. The first upper cold head module is assembled at the front end of the front shell 107, and the first lower cold head module is assembled at the rear end of the rear shell 117. The second liquid-cooling radiator 200 assembly includes a housing 215 and a second cold head module. The second cold head module is assembled at the rear end of the housing 215. The semiconductor refrigeration assembly 300 includes a semiconductor refrigeration chip 301 and a temperature control PCB 302. The temperature control PCB 302 is provided with a temperature adjustment system, which uses traditional technology. The semiconductor refrigeration chip 301 is assembled between the second cold head module and the first upper cold head module. The semiconductor refrigeration assembly 300 also includes a temperature control PCB 302, a temperature sensor, and an execution unit. The temperature control PCB 302 is electrically connected to the semiconductor refrigeration chip 301, so as to control the temperature of the semiconductor refrigeration chip 301. The temperature sensor is used to monitor the temperature of the computer in real time and convert the temperature into an electrical signal. The temperature control PCB 302 receives a temperature signal from the sensor, and compares the temperature signal with a preset temperature. According to a comparison result, the controller will send out a corresponding control signal. An actuator adjusts the temperature according to an instruction from the controller, so that the temperature control PCB 302 adjusts the cooling temperature of the semiconductor refrigeration chip 301 according to the temperature of the computer. When the computer is in a standby state, or when the power consumption generated by the computer is relatively small, the power of the semiconductor refrigeration chip 301 is also relatively low. The temperature can be adjusted to the balance of cold and heat through the temperature sensor and the temperature control PCB 302. Therefore, the problem of cooling liquid icing inside the first liquid-cooling radiator and the second liquid-cooling radiator when the semiconductor refrigeration chip 301 is working continuously and at a high power can be effectively avoided.

The first upper cold head module includes an upper waterway cover plate 115, an upper waterway rubber 110 and an upper heat sink 111 that are arranged in sequence from inside to outside. The front shell 107 is provided with a first sealing groove 116, which is configured to surround the outer periphery of a first water reservoir. A first waterway sealing ring 112 is assembled in the first sealing groove 116, and the first waterway sealing ring 112 is in contact with the inner surface of the upper heat sink 111. The first water reservoir is disposed in the middle of the front shell 107. The front shell 107 is closed by the upper waterway cover plate 115. A first water inlet tunnel 128 and a first water outlet tunnel 130 are spaced apart in the first water reservoir. A first water spray tank 109 is disposed in the middle of the upper waterway cover plate 115, and a first water trough 113 is disposed in the middle of the upper waterway rubber 110. The first water spray tank 109 communicates with the first water trough 113. A first micro water channel 133 is arranged in the upper heat sink 111. The first water inlet tunnel 128 communicates with the first water spray tank 109, and the outlet direction of the first water spray tank 109 is disposed facing the upper heat sink 111. A first water outlet 108 is disposed on each of the upper and lower sides of the upper waterway cover plate 115, and the first water outlets 108 communicate with the first water outlet tunnel 130.

The first lower cold head module includes a first lower waterway cover plate 124, a first lower waterway rubber 123 and a first lower heat sink 121 that are arranged in sequence from inside to outside. The rear shell 117 is provided with a second sealing groove configured to surround the outer periphery of the second water reservoir. A second waterway sealing ring 122 is assembled in the second sealing groove, and the second waterway sealing ring 122 is in contact with the inner surface of the first lower heat sink 121. A second water reservoir is disposed in the middle of the rear shell 117. The rear shell 117 is closed by the first lower waterway cover plate 124. A second water inlet tunnel 135 and a second water outlet tunnel 134 are spaced apart in the second water reservoir. A second water spray tank 125 is disposed in the middle of the first lower waterway cover plate 124, and a second water trough 119 is disposed in the middle of the first lower waterway rubber 123. The second water spray tank 125 communicates with the second water trough 119. A second micro water channel 120 is arranged in the first lower heat sink 121. The first lower heat sink 121 is placed close to the outer end face of the CPU, and reduces the liquid-cooled temperature of the first liquid-cooling radiator through the conduction of the semiconductor refrigeration chip 301, so as to reduce the temperature of the CPU. The second water inlet tunnel 135 communicates with the second water spray tank 125, and the outlet direction of the second water spray tank 125 is disposed facing the first lower heat sink 121. A second water outlet 118 is disposed on each of the upper and lower sides of the first lower waterway cover plate 124, and the second water outlets 118 communicate with the second water outlet tunnel 134. The front shell 107 is provided with a first water inlet orifice 127 and a first water outlet orifice 129. The rear shell 117 is provided with a first water inlet channel 101 and a first water outlet channel 102. The first water inlet channel 101 communicates with the first water inlet orifice 127. The first water inlet orifice 127 communicates with the first water inlet tunnel 128. The first water outlet orifice 129 communicates with the first water outlet tunnel 130 and the second water inlet tunnel 135 respectively. The second water outlet tunnel 134 communicates with the first water outlet channel 102. The first water-cooled pipe includes a first water inlet pipe 103 and a first water outlet pipe 104. One end of the first water inlet pipe 103 is connected to the first water inlet channel 101, and the other end of the first water inlet pipe 103 is connected to the first water-cooled row 105. One end of the first water outlet pipe 104 is connected to the first water outlet channel 102, and the other end of the first water outlet pipe 104 is connected to the first water-cooled row 105. The first water-cooled row 105 is also mounted with a first fan assembly 106, and an air inlet of the first fan assembly 106 is disposed facing the first water-cooled row 105.

The cooling liquid enters the interior of the rear shell 117 through the first water inlet pipe 103 and the first water inlet channel 101, and then flows from the first water inlet orifice 127 into the first water inlet tunnel 128. The cooling liquid passes through the first water spray tank 109 and the first water trough 113 in sequence, flows into the upper and lower sides of the first micro water channel 133 in a spraying manner, then flows from the direction of the first water outlets 108 into the first water outlet tunnel 130, and flows from the first water outlet orifice 129 into the second water inlet tunnel 135. The cooling liquid passes through the second water spray tank 125 and the second water trough 119 in sequence, flows into the upper and lower sides of the second micro water channel 120 in a spraying manner, and then flows from the direction of the second water outlets 118 into the second water outlet tunnel 134. The cooling liquid finally flows out from the first water outlet channel 102 along the first water outlet pipe 104. The cooling liquid fully contacts the first micro water channel 133 and the second micro water channel 120 in turn, so that the heat dissipation is more uniform, and the effect is better.

The second cold head module includes a second lower waterway cover plate 218, a second lower waterway rubber 205 and a second lower heat sink 203 that are arranged in sequence from inside to outside. The housing 215 is provided with a third sealing groove 213, which is configured to surround the outer periphery of the third water reservoir. A third waterway sealing ring 204 is assembled in the third sealing groove 213, and the third waterway sealing ring 204 is in contact with the inner surface of the second lower heat sink 203. A third water reservoir is disposed in the middle of the housing 215. The housing 215 is closed by the second lower waterway cover plate 218. A third water inlet tunnel 214 and a third water outlet tunnel 212 are spaced apart in the third water reservoir. A third water spray tank 209 is disposed in the middle of the second lower waterway cover plate 218, and a third water trough 207 is disposed in the middle of the second lower waterway rubber 205. The third water spray tank 209 communicates with the third water trough 207. A third micro water channel 206 is arranged in the second lower heat sink 203. The second lower heat sink 203 is placed close to the semiconductor refrigeration chip 301. The temperature of the semiconductor refrigeration chip 301 is reduced through the conduction of the second lower heat sink 203. The third water inlet tunnel 214 communicates with the third water spray tank 209, and the outlet direction of the third water spray tank 209 is disposed facing the second lower heat sink 203. A third water outlet 208 is disposed on each of the left and right sides of the second lower waterway cover plate 218, and the third water outlets 208 communicate with the third water outlet tunnel 212. The housing 215 is provided with a second water inlet channel 201 and a second water outlet channel 202. The second water inlet channel 201 communicates with the second water inlet tunnel 135, and the second water outlet channel 202 communicates with the second water outlet tunnel 134. The second water-cooled pipe includes a second water inlet pipe 210 and a second water outlet pipe 211. One end of the second water inlet pipe 210 is connected to the second water inlet channel 201, and the other end of the second water inlet pipe 210 is connected to the second water-cooled row 216. One end of the second water outlet pipe 211 is connected to the second water outlet channel 202, and the other end of the second water outlet pipe 211 is connected to the second water-cooled row 216. The second water-cooled row 216 is also mounted with a second fan assembly 217, and an air inlet of the second fan assembly 217 is disposed facing the second water-cooled row 216.

The cooling liquid enters the interior of the housing 215 through the second water inlet pipe 210 and the second water inlet channel 201, and then flows into the second water inlet tunnel 135. The cooling liquid passes through the third water spray tank 209 and the third water trough 207 in sequence, flows into the left and right sides of the third micro water channel 206 in a spraying manner, and then flows from the direction of the third water outlets 208 into the third water outlet tunnel 212. The cooling liquid finally flows out from the third water outlet channel 212 along the second water outlet pipe 211. The cooling liquid fully contacts the third micro water channel 206, so that the heat dissipation is more uniform, and the effect is better.

The first water-cooled row 105 and the second water-cooled row 216 have the same structure. The first water-cooled row 105 is provided with a first water pump 303 assembly, and the second water-cooled row 216 is provided with a second water pump 304 assembly. The first water pump 303 assembly includes a first water pump 303 and a first control circuit board. The first control circuit board is electrically connected to the first water pump 303. The first water pump 303 is installed at a connection end of the first water inlet pipe 103 and the first water-cooled row 105. The first water pump 303 is connected to the first water inlet pipe 103. The second water pump 304 assembly includes a second water pump 304 and a second control circuit board. The second control circuit board is electrically connected to the second water pump 304. The second water pump 304 is installed at a connection end of the second water inlet pipe 210 and the second water-cooled row 216. The second water pump 304 is connected to the second water inlet pipe 210.

The first water inlet pipe 103 and the first water outlet pipe 104 are connected to the rear shell 117 or the first water-cooled row 105 through an adapter 306, and a pipe sleeve 305 is provided at the connection among the first water inlet pipe 103, the first water outlet pipe 104 and the adapter 306, making the connection structure of the first water inlet pipe 103 and the first water outlet pipe 104 more reliable to reduce the risk of leakage. The second water inlet pipe 210 and the second water outlet pipe 211 are connected to the housing 215 or the second water-cooled row 216 through the adapter 306, and the pipe sleeve 305 is provided at the connection among the second water inlet pipe 210, the second water outlet pipe 211 and the adapter 306, making the connection structure of the second water inlet pipe 210 and the second water outlet pipe 211 more reliable to reduce the risk of leakage. The first water inlet pipe 103, the first water outlet pipe 104, the second water inlet pipe 210 and the second water outlet pipe 211 have the same structure, and all use a convenient structure of quick disassembly and assembly. Taking the first water inlet pipe 103 as an example, the first water inlet pipe 103 includes a first connecting pipe 310 and a second connecting pipe 307. The first connecting pipe 310 is provided with a butt joint 309 at the end close to the second connecting pipe 307. The second connecting pipe 307 is provided with a connector 308 at the end close to the first connecting pipe 310. The connector 308 and the butt joint 309 are plugged into each other to realize the connection between the first connecting pipe 310 and the second connecting pipe 307. The design of the quick disassembly and assembly structure can facilitate the transportation and installation experience of the product.

The first fan assembly 106 and the second fan assembly 217 have the same structure. The first fan assembly 106 is used to dissipate heat from the first water-cooled row 105. The second fan assembly 217 is used to dissipate heat from the second water-cooled row 216. Both the first fan assembly 106 and the second fan assembly 217 include a plurality of heat dissipation fans.

Compared with traditional art:
1. The first liquid-cooling radiator 100 assembly is connected to the first water-cooled row 105 through the first water-cooled pipe, the second liquid-cooling radiator 200 assembly is connected to the second water-cooled row 216 through the second water-cooled pipe, the first upper cold head module is assembled at the front end of the front shell 107, the first lower cold head module is assembled at the rear end of the rear shell 117, the second cold head module is assembled at the rear end of the housing 215, the semiconductor refrigeration chip 301 is assembled between the second cold head module and the first upper cold head module, and the first lower cold head module is placed close to the outer end face of the CPU. The first lower heat sink 121 is placed close to the outer end face of the CPU, and reduces the liquid-cooled temperature of the first liquid-cooling radiator through the conduction of the semiconductor refrigeration chip 301, so as to reduce the temperature of the CPU. The heat generated by the refrigeration of the semiconductor refrigeration chip 301 is conducted through the second cold head module to reduce the temperature. On the one hand, the second cold head module cools the heating surface of the semiconductor refrigeration chip 301, which can solve the problem of the semiconductor refrigeration chip 301 in the refrigeration process due to the cooling-heating imbalance, resulting in water droplets produced around the heat sink that will burn equipment of the computer. On the other hand, this structural method for cooling the temperature of the motherboard CPU goes beyond the traditional original cooling system and other cooling system methods, and can truly reduce the temperature of the motherboard CPU more effectively;
2. The first water inlet pipe 103, the first water outlet pipe 104, the second water inlet pipe 210 and the second water outlet pipe 211 have the same structure, including a first connecting pipe 310 and a second connecting pipe 307. The first connecting pipe 310 is provided with a butt joint 309 at the end close to the second connecting pipe 307, and the second connecting pipe 307 is provided with a connector 308 at the end close to the first connecting pipe 8. The connector 308 and the butt joint 309 are plugged into each other to realize the connection between the first connecting pipe 310 and the second connecting pipe 310. The design of the quick disassembly and assembly structure can facilitate the transportation and installation experience of the product;
3. The temperature control PCB 302 is provided with a temperature adjustment system. The temperature control PCB 302 is electrically connected to the semiconductor refrigeration chip 301, so as to control the temperature of the semiconductor refrigeration chip 301. The temperature sensor is used to monitor the temperature of the computer in real time and feed the temperature information back to the temperature adjustment system. The temperature control PCB 302 adjusts the cooling temperature of the semiconductor refrigeration chip 301 according to the temperature of the computer. When the computer is in a standby state, or when the power consumption generated by the computer is relatively small, the power of the semiconductor refrigeration chip 301 is also relatively low. The temperature can be adjusted to the balance of cold and heat through the temperature sensor and the temperature control PCB 302. Therefore, cooling liquid icing inside the first liquid-cooling radiator and the second liquid-cooling radiator when the semiconductor refrigeration chip 301 is working continuously and at a high power can be effectively avoided.

It is obvious to those skilled in the art that the present disclosure is not limited to the details of the above exemplary embodiments, and that the present disclosure can be implemented in other specific forms without departing from the spirit or essential characteristics of the present disclosure. Therefore, the embodiments should be regarded as illustrative and non-restrictive from any point of view, the scope of the present disclosure is defined by the appended claims rather than the above description, and it is thus intended that all changes falling within the meaning and scope of equivalent elements of claims are included in the present disclosure. Any reference numerals in the claims shall not be construed as limiting the claims involved.

1. A dual liquid-cooling radiator for a semiconductor refrigeration system, comprising a semiconductor refrigeration assembly, a first liquid-cooling radiator assembly, a second liquid-cooling radiator assembly, a first water-cooled row, a second water-cooled row, a first water-cooled pipe, and a second water-cooled pipe, wherein the first liquid-cooling radiator assembly is connected to the first water-cooled row through the first water-cooled pipe, and the second liquid-cooling radiator assembly is connected to the second water-cooled row through the second water-cooled pipe; and
the first liquid-cooling radiator assembly comprises a front shell, a rear shell, a first upper cold head module, and a first lower cold head module, the front shell and the rear shell are snap-fitted to each other, the first upper cold head module is assembled at the front end of the front shell, the first lower cold head module is assembled at the rear end of the rear shell, the second liquid-cooling radiator assembly comprises a housing and a second cold head module, the second cold head module is assembled at the rear end of the housing, and the semiconductor refrigeration assembly comprises a semiconductor refrigeration chip assembled between the second cold head module and the first upper cold head module.

2. The dual liquid-cooling radiator for a semiconductor refrigeration system according to claim 1, wherein the semiconductor refrigeration assembly further comprises a temperature control PCB electrically connected to the semiconductor refrigeration chip to control the temperature of the semiconductor refrigeration chip.

3. The dual liquid-cooling radiator for a semiconductor refrigeration system according to claim 2, wherein the first upper cold head module comprises an upper waterway cover plate, an upper waterway rubber and an upper heat sink that are arranged in sequence from inside to outside, a first water reservoir is disposed in the middle of the front shell, the front shell is closed by the upper waterway cover plate, a first water inlet tunnel and a first water outlet tunnel are spaced apart in the first water reservoir, a first water spray tank is disposed in the middle of the upper waterway cover plate, a first water trough is disposed in the middle of the upper waterway rubber, a first micro water channel is arranged in the upper heat sink, the first water inlet tunnel communicates with the first water spray tank, the outlet direction of the first water spray tank is disposed facing the upper heat sink, a first water outlet is disposed on each of the upper and lower sides of the upper waterway cover plate, and the first water outlets communicate with the first water outlet tunnel.

4. The dual liquid-cooling radiator for a semiconductor refrigeration system according to claim 3, wherein the first lower cold head module comprises a first lower waterway cover plate, a first lower waterway rubber and a first lower heat sink that are arranged in sequence from inside to outside, a second water reservoir is disposed in the middle of the rear shell, the rear shell is closed by the first lower waterway cover plate, a second water inlet tunnel and a second water outlet tunnel are spaced apart in the second water reservoir, a second water spray tank is disposed in the middle of the first lower waterway cover plate, a second water trough is disposed in the middle of the first lower waterway rubber, a second micro water channel is arranged in the first lower heat sink, the second water inlet tunnel communicates with the second water spray tank, the outlet direction of the second water spray tank is disposed facing the first lower heat sink, a second water outlet is disposed on each of the upper and lower sides of the first lower waterway cover plate, and the second water outlets communicate with the second water outlet tunnel.

5. The dual liquid-cooling radiator for a semiconductor refrigeration system according to claim 4, wherein the front shell is provided with a first water inlet orifice and a first water outlet orifice, the rear shell is provided with a first water inlet channel and a first water outlet channel, the first water inlet channel communicates with the first water inlet orifice, the first water inlet orifice communicates with the first water inlet tunnel, the first water outlet orifice communicates with the first water outlet tunnel and the second water inlet tunnel respectively, and the second water outlet tunnel communicates with the first water outlet channel.

6. The dual liquid-cooling radiator for a semiconductor refrigeration system according to claim 5, wherein the second cold head module comprises a second lower waterway cover plate, a second lower waterway rubber and a second lower heat sink that are arranged in sequence from inside to outside, a third water reservoir is disposed in the middle of the housing, the housing is closed by the second lower waterway cover plate, a third water inlet tunnel and a third water outlet tunnel are spaced apart in the third water reservoir, a third water spray tank is disposed in the middle of the second lower waterway cover plate, a third water trough is disposed in the middle of the second lower waterway rubber, a third micro water channel is arranged in the second lower heat sink, the third water inlet tunnel communicates with the third water spray tank, the outlet direction of the third water spray tank is disposed facing the second lower heat sink, a third water outlet is disposed on each of the left and right sides of the second lower waterway cover plate, and the third water outlets communicate with the third water outlet tunnel.

7. The dual liquid-cooling radiator for a semiconductor refrigeration system according to claim 6, wherein the housing is provided with a second water inlet channel and a second water outlet channel, the second water inlet channel communicates with the second water inlet tunnel, and the second water outlet channel communicates with the second water outlet tunnel.

8. The dual liquid-cooling radiator for a semiconductor refrigeration system according to claim 7, wherein the front shell is provided with a first sealing groove configured to surround the outer periphery of the first water reservoir, a first waterway sealing ring is assembled in the first sealing groove, the first waterway sealing ring is in contact with the inner surface of the upper heat sink, the rear shell is provided with a second sealing groove configured to surround the outer periphery of the second water reservoir; a second waterway sealing ring is assembled in the second sealing groove, and the second waterway sealing ring is in contact with the inner surface of the first lower heat sink; the housing is provided with a third sealing groove configured to surround the outer periphery of the third water reservoir; a third waterway sealing ring is assembled in the third sealing groove, and the third waterway sealing ring is in contact with the inner surface of the second lower heat sink.

9. The dual liquid-cooling radiator for a semiconductor refrigeration system according to claim 8, wherein the first water-cooled pipe comprises a first water inlet pipe and a first water outlet pipe, one end of the first water inlet pipe is connected to the first water inlet channel, the other end of the first water inlet pipe is connected to the first water-cooled row, one end of the first water outlet pipe is connected to the first water outlet channel, the other end of the first water outlet pipe is connected to the first water-cooled row, the first water-cooled row is further mounted with a first fan assembly, and an air inlet of the first fan assembly is disposed facing the first water-cooled row.

10. The dual liquid-cooling radiator for a semiconductor refrigeration system according to claim 9, wherein the second water-cooled pipe comprises a second water inlet pipe and a second water outlet pipe, one end of the second water inlet pipe is connected to the second water inlet channel, the other end of the second water inlet pipe is connected to the second water-cooled row, one end of the second water outlet pipe is connected to the second water outlet channel, the other end of the second water outlet pipe is connected to the second water-cooled row, the second water-cooled row is further mounted with a second fan assembly, and an air inlet of the second fan assembly is disposed facing the second water-cooled row.
